(19) United States
(12) Patent Application Publication
(10) Pub. No.: US 2021/0272872 A1
(43) Pub. Date: Sep. 2, 2021

(54) THERMAL MANAGEMENT MATERIALS FOR SEMICONDUCTOR DEVICES, AND ASSOCIATED SYSTEMS AND METHODS

(71) Applicant: Micron Technology, Inc., Boise, ID (US)

(72) Inventors: Xiaopeng Qu, Boise, ID (US); Hyunsuk Chun, Boise, ID (US); Eiichi Nakano, Boise, ID (US); Amy R. Griffin, Boise, ID (US)

(21) Appl. No.: 16/807,075

(22) Filed: Mar. 2, 2020

(51) Int. Cl. H01L 23/373; H01L 23/433

(52) U.S. Cl. CPC H01L 23/373; H01L 23/4334

(57) ABSTRACT

Semiconductor devices including materials for thermal management, and associated systems and methods, are described herein. In some embodiments, a semiconductor package includes a first semiconductor die coupled to a second semiconductor die by a plurality of interconnect structures. A thermal material can be positioned between the first and second semiconductor dies. The thermal material can include an array of heat transfer elements embedded in a supporting matrix material. The array of heat transfer elements can include at least one vacant region aligned with at least one of the interconnect structures.

### TECHNICAL FIELD

The present technology generally relates to semiconductor devices, and more particularly relates to materials for thermal management in semiconductor devices.

### BACKGROUND

Packaged semiconductor dies, including memory chips, microprocessor chips, and imager chips, typically include a semiconductor die mounted on a substrate and encased in a protective covering. The semiconductor die can include functional features, such as memory cells, processor circuits, and imager devices, as well as bond pads electrically connected to the functional features. The bond pads can be electrically connected to terminals outside the protective covering to allow the semiconductor die to be connected to higher level circuitry.

Market pressures continually drive semiconductor manufacturers to reduce the size of die packages to fit within the space constraints of electronic devices, while also driving them to increase the functional capacity of each package to meet operating parameters. One approach for increasing the processing power of a semiconductor package without substantially increasing the surface area covered by the package (the package's “footprint”) is to vertically stack multiple semiconductor dies on top of one another in a single package. The dies in such vertically stacked packages can be interconnected by electrically coupling the bond pads of the individual dies with the bond pads of adjacent dies using through-silicon vias (TSVs).

A challenge associated with vertically stacked die packages is that the heat generated by the individual dies is additive, and it can be difficult to dissipate the aggregated heat generated by the stacked dies. This additive heat increases the operating temperatures of the individual dies, the junctions between the dies, and the package as a whole, which can cause the stacked dies to reach temperatures above their maximum operating temperatures (Tₘₐₓ). This problem can be exacerbated as the density of the dies in the package increases. Moreover, when devices have different types of dies in the die stack, the maximum operating temperature of the device can be limited to the die with the lowest maximum operating temperature.

### BRIEF DESCRIPTION OF THE DRAWINGS

Many aspects of the present technology can be better understood with reference to the following drawings. The components in the drawings are not necessarily to scale. Instead, emphasis is placed on illustrating clearly the principles of the present technology.

FIG. 1 is a side cross-sectional view of a semiconductor package configured in accordance with embodiments of the present technology.

FIGS. 2A-2C are side cross-sectional views of a thermal material at various stages of manufacture in accordance with embodiments of the present technology.

FIG. 3 is a block diagram illustrating a method for manufacturing a semiconductor package in accordance with embodiments of the present technology.

FIG. 4 is a graph illustrating enhancement of thermal conductivity in a thermal material configured in accordance with embodiments of the present technology.

FIG. 5 is a graph illustrating decrease in junction temperature with increasing thermal conductivity of the thermal material of FIG. 4.

FIG. 6 is a schematic view of a system that includes a semiconductor device or package configured in accordance with embodiments of the present technology.

### DETAILED DESCRIPTION

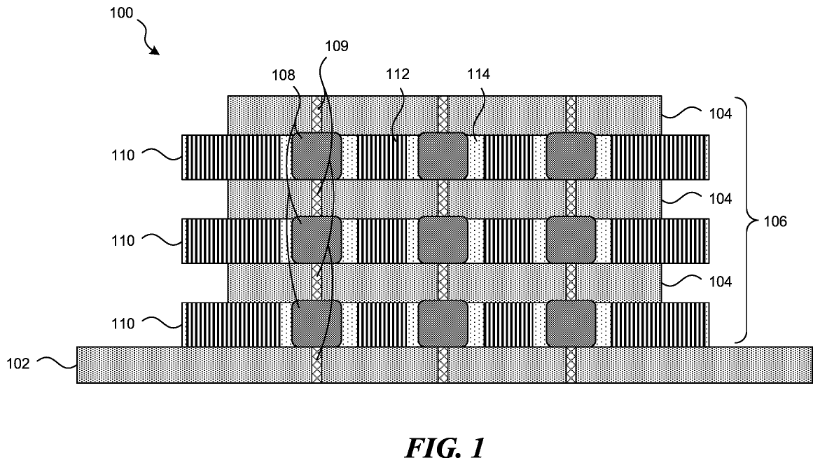

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques. A person skilled in the relevant art will also understand that the technology may have additional embodiments, and that the technology may be practiced without several of the details of the embodiments described below with reference to FIGS. 1-6.

In several of the embodiments described below, a semiconductor package includes a first semiconductor die coupled to a second semiconductor die by a plurality of interconnect structures (e.g., as part of a semiconductor die stack). A thermal material can be positioned between the first and second semiconductor dies. The thermal material can include an array of heat transfer elements (e.g., carbon nanotubes) embedded in a supporting matrix material (e.g., a non-conductive film, an underfill material, etc.). The array of heat transfer elements can be patterned to form at least one vacant region aligned with at least one of the interconnect structures. The thermal material can exhibit a higher thermal conductivity compared to the supporting matrix material alone. Accordingly, the thermal material can be used to increase heat transfer between the semiconductor dies (e.g., out of the die stack), which is expected to reduce the overall operating temperature of the semiconductor package and improve thermal performance.

Numerous specific details are disclosed herein to provide a thorough and enabling description of embodiments of the present technology. A person skilled in the art, however, will understand that the technology may have additional embodiments and that the technology may be practiced without several of the details of the embodiments described below with reference to FIGS. 1-6. For example, some details of semiconductor devices and/or packages well known in the art have been omitted so as not to obscure the present technology. In general, it should be understood that various other devices and systems in addition to those specific embodiments disclosed herein may be within the scope of the present technology.

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

Although certain embodiments herein are described with respect to thermal materials for high heat transfer rates between two semiconductor dies, it shall be appreciated that the present technology is equally applicable to thermal materials for increasing heat transfer between other semiconductor device components, e.g., a semiconductor die and a package substrate.

FIG. 1 is a side cross-sectional view of a semiconductor package 100 (“package 100”) configured in accordance with embodiments of the present technology. The package 100 can include a first semiconductor die 102 (“first die 102”) and a plurality of second semiconductor dies 104 (“second die(s) 104”) mounted on the first die 102. The second semiconductor dies 104 can be vertically arranged to form a die stack 106. In the illustrated embodiment, the die stack 106 includes three second semiconductor dies 104. In other embodiments, the die stack 106 can include fewer or more second semiconductor dies 104 (e.g., two, four, five, six, seven, eight nine, ten, or more dies).

The first die 102 and/or the second dies 104 can each include a semiconductor substrate (e.g., a silicon substrate, a gallium arsenide substrate, an organic laminate substrate, etc.). In some embodiments, one or more of the first die 102 and/or the second dies 104 include various types of semiconductor components and functional features, such as memory circuits (e.g., dynamic random-access memory (DRAM), static random-access memory (SRAM), flash memory, or other type of memory circuits), controller circuits (e.g., DRAM controller circuits), logic circuits, processing circuits, circuit elements (e.g., wires, traces, interconnects, transistors, etc.), imaging components, and/or other semiconductor features. For example, the package 100 can be a hybrid memory cube (HMC) in which the stacked second dies 104 are DRAM dies or other memory dies that provide data storage and the first die 102 is a high-speed logic die that provides memory control (e.g., DRAM control) within the HMC. Alternatively or in combination, one or more of the first die 102 and/or the second dies 104 can be a “blank” substrate that does not include integrated circuit components and that is formed from, for example, crystalline, semi-crystalline, and/or ceramic substrate materials, such as silicon, polysilicon, aluminum oxide (Al₂O₃), sapphire, and/or other suitable materials. Optionally, the first die 102 and/or the second dies 104 can include an insulating material, such as a suitable dielectric material (e.g., a passivation material, a polyimide material, and/or other materials used to cover a surface of a semiconductor device).

The first die 102 and/or second dies 104 can be coupled (e.g., mechanically, thermally, and/or electrically) to each other by a plurality of interconnect structures 108 (e.g., bumps, micro-bumps, pillars, columns, studs, etc.). Each interconnect structure 108 can be formed of any suitably conductive material such as copper, nickel, gold, silicon, tungsten, solder (e.g., SnAg-based solder), conductive-epoxy, combinations thereof, etc., and can be formed by electroplating, electroless-plating, or another suitable process. In some embodiments, the interconnect structures 108 can also include barrier materials (e.g., nickel, nickel-based intermetallic, and/or gold) formed over end portions of the interconnect structures 108. The barrier materials can facilitate bonding and/or prevent or at least inhibit the electromigration of copper or other metals used to form the interconnect structures 108.

In some embodiments, at least some of the interconnect structures 108 are electrically coupled to the first die 102 and/or the second dies 104 (e.g., to TSVs 109 located within the first die 102 and/or the second dies 104). Alternatively or in combination, at least some of the interconnect structures 108 can be “dummy” structures that are not electrically coupled to the first die 102 and/or second dies 104. Optionally, at least some of the interconnect structure can be thermal bumps that thermally couple the first die 102 and/or second dies 104 to reduce thermal resistance between dies. While nine interconnect structures 108 are illustrated in FIG. 1, the package 100 can include fewer or more interconnect structures 108. For example, the package 100 can include tens, hundreds, thousands, or more interconnect structures 108 arrayed between the first die 102 and/or second dies 104.

The package 100 further includes a thermal material 110 for thermal management of the package 100, e.g., by increasing heat transfer and/or reducing thermal resistance between dies. In the illustrated embodiment, the thermal material 110 is positioned between the first die 102 and the bottom-most second die 104, and between each of the second dies 104. The thermal material 110 can be configured to surround the interconnect structures 108. In some embodiments, the thermal material 110 includes a plurality of holes formed therein to receive the interconnect structures 108. Optionally, the thermal material 110 can be omitted from some portions of the package 100. Additionally, although FIG. 1 depicts the outer edges of the thermal material 110 as protruding beyond the outer edges of the die stack 106, in other embodiments, the outer edges of the thermal material 110 can be aligned with the outer edges of the die stack 106 or positioned fully within the interior of the die stack 106.

In some embodiments, the thermal material 110 is a composite material including different types of materials. For example, the composite material can include a plurality of heat transfer elements 112 embedded in a supporting matrix material 114. Various types of heat transfer elements 112 are suitable for use with the embodiments disclosed herein. For example, the heat transfer elements 112 can be made of any suitable material having a relatively high thermal conductivity, such as metals (e.g., copper) or carbon-based materials (e.g., graphite, graphene, carbon nanotubes). The heat transfer elements 112 can be structured in many different ways, such as particles, fibers, wires, tubes, meshes, or combinations thereof. In some embodiments, the heat transfer elements 112 are nanoscale or nanostructured elements, such as nanoparticles, nanofibers, nanotubes, nanowires, etc.

The heat transfer elements 112 can be configured as desired. For example, the heat transfer elements 112 can be arranged in an organized configuration, such as an array. The heat transfer elements 112 can be aligned with each other within the array (e.g., vertically aligned). In other embodiments, the heat transfer elements 112 can be randomly dispersed in regions of the supporting matrix material 114 without any particular organization and/or alignment within a given region. Optionally, the heat transfer elements 112 can be patterned or otherwise formed with at least one vacant region such that some regions of the thermal material 110 have heat transfer elements 112 while other regions of the thermal material 110 do not have heat transfer elements 112. The vacant region(s) can be sized and shaped to accommodate components of the package 100 (e.g., interconnect structures 108), as described in greater detail below. For example, the heat transfer elements 112 can be configured as a material sheet or layer that is patterned with a plurality of vacant regions at discrete locations. As another example, the heat transfer elements 112 can be configured as one or more discrete material sections (e.g., strips, segments, patches, etc.) that are spaced apart or otherwise separated from each other to form at least one vacant region.

In some embodiments, the heat transfer elements 112 are an array of carbon nanotubes. The carbon nanotubes can be single-walled nanotubes or multi-walled nanotubes (e.g., double-walled, triple-walled, etc.). Each carbon nanotube can have an elongated shape extending along a longitudinal axis, e.g., with an aspect ratio greater than or equal to 10:1, 100:1, 1000:1, 10000:1, 10⁵:1, 10⁶:1, or more. The carbon nanotubes can be vertically aligned with each other along their longitudinal axes. As a result, the array of carbon nanotubes is expected to collectively exhibit a high thermal conductivity along the vertical direction to reduce thermal resistance and enhance heat transfer between dies.

The supporting matrix material 114 can be any material suitable for filling spaces between the heat transfer elements 112, such as a film, underfill, resin, paste, etc. The supporting matrix material 114 can also mechanically support and/or hold the heat transfer elements 112 together. The supporting matrix material 114 can be made of a material with a relatively low thermal conductivity compared to the heat transfer elements 112, such as a polymeric material. For example, the supporting matrix material 114 can be a non-conductive film or a die attach film. In some embodiments, the supporting matrix material 114 is an underfill material, such as a nonconductive epoxy paste (e.g., XS8448-171 manufactured by Namics Corporation of Niigata, Japan), a capillary underfill, and/or other suitable electrically insulative materials. The underfill material 110 can alternatively be a dielectric underfill, such as FP4585 manufactured by Henkel of Dusseldorf, Germany. Optionally, the supporting matrix material 114 can be patterned, e.g., with a plurality of holes to accommodate components of the package 100 (e.g., interconnect structures 108), as described in greater detail below.

The composition of the thermal material 110 (e.g., the relative amounts of heat transfer elements 112 and supporting matrix material 114) can be selected to improve the thermal properties of the thermal material 110. In some embodiments, the heat transfer elements 112 constitute at least 10%, 20%, 30%, 40%, 50%, 60%, 70%, 80%, or 90% by weight of the thermal material 110. In some embodiments, the supporting matrix material 114 constitutes at least 10%, 20%, 30%, 40%, 50%, 60%, 70%, 80%, or 90% by weight of the thermal material 110. In some embodiments, the thermal conductivity of the thermal material 110 is sufficiently high such that a maximum operating temperature of the package 100 (e.g., junction temperature) is less than or equal to 110° C., 105° C., 100° C., 95° C., or less. For example, the thermal material 110 can have a thermal conductivity greater than or equal to 5 W/mK, 10 W/mK, 15 W/mK, 20 W/mK, 25 W/mK, or more.

The package 100 can include other components typically found in semiconductor devices and known to one of skill in the art. For example, the first die 102 can be mounted on a package substrate (not shown), such as a redistribution layer, an interposer, a printed circuit board, a dielectric spacer, another semiconductor die (e.g., a logic die), or another suitable substrate. The package substrate can include semiconductor components (e.g., doped silicon wafers or gallium arsenide wafers), nonconductive components (e.g., various ceramic substrates, such as aluminum oxide (Al₂O₃), etc.), aluminum nitride, and/or conductive portions (e.g., interconnecting circuitry, TSVs, etc.). The package substrate can further include electrical connectors (e.g., solder balls, conductive bumps, conductive pillars, conductive epoxies, and/or other suitable electrically conductive elements) electrically coupled to the package substrate and configured to electrically couple the package 100 to external devices or circuitry (not shown). In some embodiments, the package 100 includes other components such as external heatsinks, a casing (e.g., thermally conductive casing), electromagnetic interference (EMI) shielding components, etc.

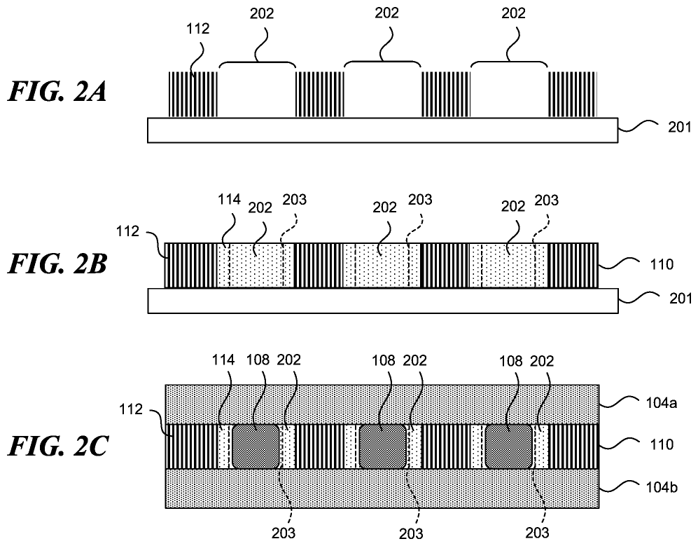

FIGS. 2A-2C are side cross-sectional views of the thermal material 110 at various stages of manufacture, in accordance with embodiments of the present technology. FIG. 2A illustrates a plurality of heat transfer elements 112 (e.g., an array of carbon nanotubes) formed on a substrate 201. The heat transfer elements 112 can be patterned or otherwise formed with a plurality of vacant regions 202 (e.g., holes, apertures, spaces, grooves, channels, separations, etc.) to accommodate the various components of the semiconductor package. For example, the vacant regions 202 can be configured to accommodate interconnect structures (e.g., interconnect structures 108 described with respect to FIG. 1). In some embodiments, each vacant region 202 is configured to receive a single interconnect structure. In other embodiments, each vacant region 202 can be configured to receive multiple interconnect structures (e.g., two, three, four, five, 10, 20, 50, 100, or more interconnect structures). Additionally, the dimensions (e.g., length, width, diameter, area) and/or spacing (e.g., pitch) of the vacant regions 202 can be designed to reduce or avoid electrical interference with the interconnect structures 108. In some embodiments, the cross-sectional shape of the vacant regions 202 can be identical or similar to the cross-sectional shape of the interconnect structures 108 (e.g., circular, elliptical, square, rectangular, polygonal, rectilinear, or curvilinear, or a combination thereof). The cross-sectional dimension (e.g., cross-sectional area, diameter, width, etc.) of the vacant regions 202 can be identical or similar to the cross-sectional dimension of the interconnect structures 108. In other embodiments, the cross-sectional dimension of the vacant regions 202 can be greater than the cross-sectional dimension of the interconnect structures 108 (e.g., greater by at least 10%, 20%, 30%, 40%, 50%, 60%, 70%, 80%, 90%, 100%, or more).

FIG. 2B illustrates the heat transfer elements 112 embedded in a supporting matrix material 114 to form the thermal material 110. The process of embedding the heat transfer elements 112 in the supporting matrix material 114 can be performed while the heat transfer elements 112 are still attached to the substrate 201. In other embodiments, the heat transfer elements 112 can be removed from the substrate 201 before being embedded in the supporting matrix material 114. The supporting matrix material 114 can fill interstitial spaces between the heat transfer elements 112 and/or the vacant regions 202. In some embodiments, the heat transfer elements 112 are entirely embedded in the supporting matrix material 114. In other embodiments, only a portion of the heat transfer elements 112 are embedded in the supporting matrix material 114. For example, in embodiments where the heat transfer elements 112 are vertically aligned, the upper and/or lower ends of the heat transfer elements 112 can protrude out of the upper and/or lower surfaces, respectively, of the supporting matrix material 114.

Optionally, the supporting matrix material 114 can be patterned with a plurality of holes 203 shown in dashed lines in which various components of the semiconductor package (e.g., interconnect structures 108) can be received. The holes 203 can have the same size and/or shape as the vacant regions 202 formed in the array of heat transfer elements 112, or the holes 203 can have a smaller cross-sectional dimension than the vacant regions 202. In some embodiments, the cross-sectional shape of the holes 203 can be identical or similar to the cross-sectional shape of the interconnect structures 108 (e.g., circular, elliptical, square, rectangular, polygonal, rectilinear, or curvilinear, or a combination thereof). The cross-sectional dimension (e.g., cross-sectional area, diameter, width, etc.) of the holes 203 can be identical or similar to the cross-sectional dimension of the interconnect structures 108. In other embodiments, the cross-sectional dimension of the holes 203 can be greater than the cross-sectional dimension of the interconnect structures 108 (e.g., greater by at least 10%, 20%, 30%, 40%, 50%, 60%, 70%, 80%, 90%, 100%, or more). In other embodiments, the supporting matrix material 114 is formed without any holes or other patterning.

FIG. 2C illustrates a stage of the process after the thermal material 110 has been removed from the substrate 201 and positioned between a first semiconductor die 104a and a second semiconductor die 104b. In the illustrated embodiment, the interconnect structures 108 between the first and second semiconductor dies 104a, 104b are aligned with and pass through the vacant regions 202 formed in the array of heat transfer elements 112. The interconnect structures 108 also pass through the supporting matrix material 114. In embodiments where the supporting matrix material 114 is patterned with holes 203, each interconnect structure 108 can pass through a corresponding hole 203 in the supporting matrix material 114. In other embodiments, the supporting matrix material 114 can be initially formed without any holes, and holes can subsequently be formed in the supporting matrix material 114 during the process of coupling the first semiconductor die 104a, second semiconductor die 104b, interconnect structures 108, and/or thermal material 110 to each other, as described in detail below.

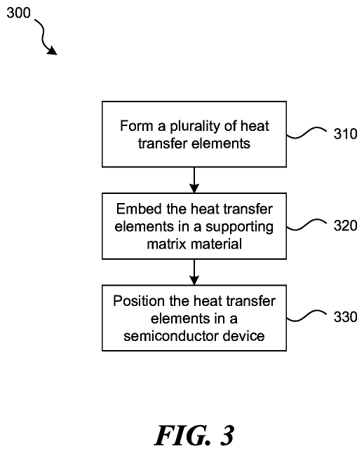

FIG. 3 is a block diagram illustrating a method 300 for manufacturing a semiconductor package, in accordance with embodiments of the present technology. The method 300 can be used to manufacture any embodiment of the devices and systems described herein (e.g., semiconductor package 100 described with respect to FIG. 1), or components thereof (e.g., thermal material 110 described with respect to FIGS. 1-2C).

The method 300 includes forming a plurality of heat transfer elements (block 310). As previously described, the heat transfer elements can be an array of heat transfer elements, such as an array of nanoscale thermally conductive elements. In embodiments where the heat transfer elements are an array of carbon nanotubes, the carbon nanotubes can be formed according to processes known to those of skill in the art. For example, vertically-aligned carbon nanotubes can be grown on a substrate (e.g., silicon) using techniques such as chemical vapor deposition (CVD) (e.g., thermal CVD, plasma-enhanced CVD) or electrophoretic deposition.

The heat transfer elements can be patterned or otherwise formed with at least one vacant region, e.g., as described with respect to FIG. 2A. The patterning can be performed in a variety of different ways as is known to those of skill in the art. For example, in some embodiments, the heat transfer elements are initially formed as a uniform, un-patterned material without the vacant region(s) (e.g., a continuous array of heat transfer elements without vacant regions). Subsequently, one or more portions of the uniform material can be removed (e.g., by etching, transferring, etc.) to create the vacant region(s) within the array and/or to separate portions of the array from each other. Alternatively or in combination, the heat transfer elements can be formed at selected locations (e.g., by growing on a patterned substrate or catalyst) to create the vacant region(s). For example, in embodiments where the heat transfer elements are an array of carbon nanotubes, the array can be patterned with one or more vacant regions by growing a uniform array on a first substrate. Subsequently, one or more portions of the array can be selectively transferred to a patterned second substrate. The vacant region(s) can correspond to locations where the carbon nanotubes were not transferred to the second substrate.

The method 300 further includes embedding the heat transfer elements in a supporting matrix material (block 320). The heat transfer elements can be at least partially or fully embedded in the supporting matrix material, e.g., as previously described with respect to FIG. 2B. The embedding process can be performed using techniques known to those of skill in the art. For example, in some embodiments, the supporting matrix material can be flowed, injected, poured, etc. into the heat transfer elements in order to surround and encapsulate individual heat transfer elements. In such embodiments, the supporting matrix material can be a capillary underflow material suitable for infiltrating into the interstitial spaces between individual heat transfer elements by capillary action. Alternatively or in combination, the heat transfer elements can be embedded by pressing into the supporting matrix material. Once the supporting matrix material is in place, it can be cured in order to bond the supporting matrix material to the heat transfer elements.

The method further includes positioning the heat transfer elements in a semiconductor device (block 330). As previously described with respect to FIG. 2C, the heat transfer elements can be positioned between a first semiconductor die and a second semiconductor die. In some embodiments, the first and second semiconductor dies are configured to be coupled to each other by a plurality of interconnect structures, such that the positioning process includes aligning the vacant region(s) formed in the heat transfer elements with the interconnect structures so that the interconnect structures pass through the vacant region(s). Each interconnect structure can pass through a corresponding vacant region, or multiple interconnect structures can pass through a single vacant region. The heat transfer elements can subsequently be coupled to the first and second dies (e.g., by thermo-compression bonding (TCB)).

The supporting matrix material can be positioned in the semiconductor device (e.g., between the first and second dies) along with the heat transfer elements. In some embodiments, the supporting matrix material is provided as a film (e.g., non-conductive film), and the interconnect structures are pressed through or otherwise displace the supporting matrix material to contact the other semiconductor die. Optionally, the film can be patterned with holes aligned with the interconnect structures, such that each interconnect structure passes through a corresponding hole in the film during the positioning process. The first semiconductor die, second semiconductor die, interconnect structures, heat transfer elements, and supporting matrix material can subsequently be coupled to each other, e.g., by a TCB operation.

The method 300 can be performed in a variety of different ways and the steps of the method 300 can be performed in any suitable order. For example, the heat transfer elements can be positioned in the semiconductor device before embedding the heat transfer elements in the supporting matrix material. In such embodiments, after the heat transfer elements are positioned, the supporting matrix material can be flowed between the first and second dies to fill interstitial spaces between the heat transfer elements and/or the interconnect structures. As another example, the heat transfer elements can be formed on one of the semiconductor dies (e.g., the first or second die) and subsequently coupled to the other semiconductor die. In such embodiments, the supporting matrix material can be introduced before, concurrently with, or after coupling with the other semiconductor die.

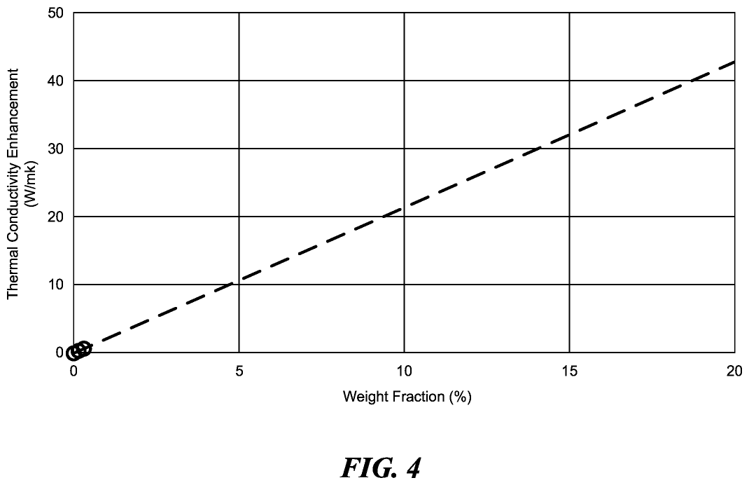

FIG. 4 is a graph illustrating enhancement of thermal conductivity in a thermal material configured in accordance with embodiments of the present technology. In the illustrated embodiment, the thermal material is a non-conductive film with an embedded array of vertically-aligned carbon nanotubes. As can be seen in FIG. 4, the overall thermal conductivity of the material increases as the weight fraction of the carbon nanotubes increases. For instance, a 10% weight fraction of carbon nanotubes corresponds to a thermal conductivity of approximately 20 W/mK.

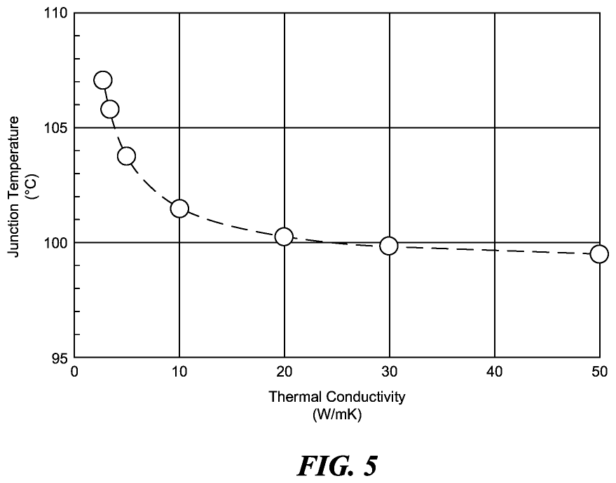

FIG. 5 is a graph illustrating decrease in junction temperature with increasing thermal conductivity of the thermal material of FIG. 4. Referring to FIGS. 4 and 5 together, the thermal conductivity of a non-conductive film without any carbon nanotubes is approximately 2.7 W/mK, which corresponds to a junction temperature of approximately 107.1° C. In contrast, a non-conductive film with a 10% weight fraction of carbon nanotubes has a thermal conductivity of approximately 20 W/mK, which corresponds to a junction temperature of approximately 100.2° C. As can be seen in FIG. 5, the incorporation of carbon nanotubes can significantly reduce the junction temperature of the semiconductor package and improve thermal performance.

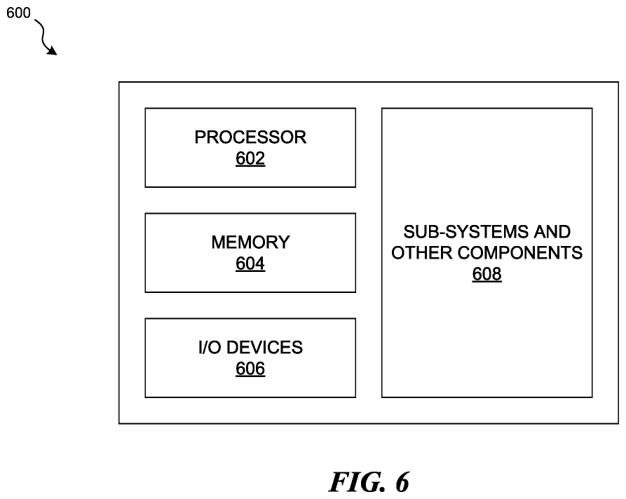

Any one of the semiconductor devices and/or packages having the features described above with reference to FIGS. 1-5 can be incorporated into any of a myriad of larger and/or more complex systems, a representative example of which is system 600 shown schematically in FIG. 6. The system 600 can include a processor 602, a memory 604 (e.g., SRAM, DRAM, flash, and/or other memory devices), input/output devices 606, and/or other subsystems or components 608. The semiconductor dies and/or packages described above with reference to FIGS. 1-5 can be included in any of the elements shown in FIG. 6. The resulting system 600 can be configured to perform any of a wide variety of suitable computing, processing, storage, sensing, imaging, and/or other functions. Accordingly, representative examples of the system 600 include, without limitation, computers and/or other data processors, such as desktop computers, laptop computers, Internet appliances, hand-held devices (e.g., palm-top computers, wearable computers, cellular or mobile phones, personal digital assistants, music players, etc.), tablets, multi-processor systems, processor-based or programmable consumer electronics, network computers, and minicomputers. Additional representative examples of the system 600 include lights, cameras, vehicles, etc. With regard to these and other example, the system 600 can be housed in a single unit or distributed over multiple interconnected units, e.g., through a communication network. The components of the system 600 can accordingly include local and/or remote memory storage devices and any of a wide variety of suitable computer-readable media.

From the foregoing, it will be appreciated that specific embodiments of the technology have been described herein for purposes of illustration, but that various modifications may be made without deviating from the disclosure. Accordingly, the invention is not limited except as by the appended claims. Furthermore, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

I/We claim:

1. A semiconductor package, comprising:
a first semiconductor die;
a second semiconductor die;
a plurality of interconnect structures coupling the first and second semiconductor dies; and
a thermal material between the first and second semiconductor dies and surrounding the interconnect structures, wherein the thermal material includes—
a supporting matrix material, and
an array of heat transfer elements at least partially embedded in the supporting matrix material, wherein the array of heat transfer elements has at least one vacant region aligned with at least one of the interconnect structures.

2. The semiconductor package of claim 1 wherein the array of heat transfer elements comprises nanoscale elements.

3. The semiconductor package of claim 2 wherein the nanoscale elements are aligned with each other.

4. The semiconductor package of claim 2 wherein the array of heat transfer elements comprises carbon nanotubes.

5. The semiconductor package of claim 4 wherein the carbon nanotubes are vertically aligned so as to facilitate heat transfer between the first and second semiconductor dies.

6. The semiconductor package of claim 1 wherein the supporting matrix material comprises a non-conductive film or an underfill material.

7. The semiconductor package of claim 1 wherein the supporting matrix material fills interstitial spaces between individual heat transfer elements of the array of heat transfer elements.

8. The semiconductor package of claim 1 wherein the supporting matrix material is patterned to form a plurality of holes aligned with the plurality of interconnect structures.

9. The semiconductor package of claim 1 wherein the array of heat transfer elements has a higher thermal conductivity than the supporting matrix material.

10. The semiconductor package of claim 1 wherein the thermal material has a thermal conductivity of at least 20 W/mK.

11. The semiconductor package of claim 1 wherein the array of heat transfer elements is at least 10% by weight of the thermal material.

12. The semiconductor package of claim 1 wherein the array of heat transfer elements has a plurality of vacant regions aligned with the plurality of interconnect structures.

13. A method of manufacturing a semiconductor package, the method comprising:
forming an array of heat transfer elements including a plurality of vacant regions;
embedding at least a portion of the array of heat transfer elements in a supporting matrix material; and
positioning the array of heat transfer elements between a first semiconductor die and a second semiconductor die, wherein the first and second semiconductor dies are coupled to each other by a plurality of interconnect structures, and wherein the plurality of interconnect structures are aligned with the plurality of vacant regions.

14. The method of claim 13 wherein the array of heat transfer elements comprises carbon nanotubes.

15. The method of claim 13 wherein forming the array of heat transfer elements comprises:
forming a uniform array of heat transfer elements; and
removing one or more portions of the uniform array of heat transfer elements to create the plurality of vacant regions.

16. The method of claim 13 wherein forming the array of heat transfer elements comprises forming heat transfer elements at selected locations so as to create the plurality of vacant regions.

17. The method of claim 13 wherein the array of heat transfer elements is formed on a surface of the first or second semiconductor die.

18. The method of claim 13 wherein the array of heat transfer elements is coupled to the first and second semiconductor dies after being formed.

19. The method of claim 13 wherein the embedding step comprises flowing the supporting matrix material into interstitial spaces between individual heat transfer elements of the array of heat transfer elements.

20. The method of claim 13 wherein the embedding step is performed before positioning the array of heat transfer elements between the first and second semiconductor dies.

21. The method of claim 13 wherein the embedding step is performed after positioning the array of heat transfer elements between the first and second semiconductor dies.
